(19) United States
(12) Patent Application Publication
(10) Pub. No.: US 2024/0202067 A1
(43) Pub. Date: Jun. 20, 2024

(54) STORAGE DEVICE AND METHOD OF OPERATING THE SAME

(71) Applicant: SAMSUNG ELECTRONICS CO., LTD., SUWON-SI (KR)

(72) Inventors: Seonghyeog CHOI, Suwon-si (KR); Changkyu Seol, Suwon-si (KR); Dong Kim, Suwon-si (KR); Inhoon Park, Suwon-si (KR); Jinsoo Lim, Suwon-si (KR); Youngdon Choi, Suwon-si (KR); Junghwan Choi, Suwon-si (KR)

(21) Appl. No.: 18/223,124

(22) Filed: Jul. 18, 2023

(30) Foreign Application Priority Data
Dec. 16, 2022 (KR) 10-2022-0177436

(51) Int. Cl. G06F 11/10

(52) U.S. Cl. CPC G06F 11/10

(57) ABSTRACT

A method of operating a storage device includes: periodically performing a patrol read operation on a memory device; storing failure information according to the patrol read operation in a buffer memory; generating an uncorrectable error as a result of a first error correction operation performed on read data of the memory device; loading the failure information from the buffer memory; and performing a second error correction operation on the read data by using the failure information.

### CROSS-REFERENCE TO RELATED APPLICATION

This application claims priority under 35 U.S.C. § 119 to Korean Patent Application No. 10-2022-0177436 filed on Dec. 16, 2022 in the Korean Intellectual Property Office, the disclosure of which is incorporated by reference herein in its entirety.

### TECHNICAL FIELD

The present inventive concept relates to a storage device and a method of operating the same.

### DISCUSSION OF THE RELATED ART

In general, it may be difficult to ensure cell reliability due to the process refinement of a dynamic random access memory (DRAM). When a failure occurs in DRAM in a solid state drive (SSD), a firmware operation of the SSD may be impacted. In some cases, a central processing unit (CPU) of the SSD may fall into an exception and the SSD might not operate. For this reason, for the SSD, technologies for storing/managing failure information such as on-die ECC, sub wordline (SWL)/sub wordline drive (SWD), or the like may be under development for DRAM management therein.

### SUMMARY

According to an embodiment of the present inventive concept, a method of operating a storage device includes: periodically performing a patrol read operation on a memory device; storing failure information according to the patrol read operation in a buffer memory; generating an uncorrectable error as a result of a first error correction operation performed on read data of the memory device; loading the failure information from the buffer memory; and performing a second error correction operation on the read data by using the failure information.

According to an embodiment of the present inventive concept, a storage device includes: at least one non-volatile memory device; a memory device; and a controller configured to control the at least one non-volatile memory device, wherein the controller periodically collects failure information of the memory device through a patrol read operation, and determines an erasure using the failure information, wherein the controller performs an error correction operation on read data by using the determined erasure.

According to an embodiment of the present inventive concept, a method of operating a storage device includes: performing a first error correction operation on read data of a memory device; and performing a second error correction operation by using failure information of the memory device when an error of the read data is uncorrectable as determined by the first error correction operation.

According to an embodiment of the present inventive concept, a storage device includes: at least one processor configured to control an overall operation of a controller; a memory device; a memory controller configured to control the memory device; and a buffer memory configured to store health information of the memory device, wherein the at least one processor collects the health information by driving a memory manager to periodically monitor the memory device, and the memory controller performs error correction decoding on read data of the memory device by using the health information.

### BRIEF DESCRIPTION OF DRAWINGS

The above and other aspects of the present inventive concept will become more apparent by describing in detail example embodiments thereof, with reference to the accompanying drawings, in which:

FIG. 1 is a view illustrating a storage device according to an embodiment of the present inventive concept.

FIGS. 2A, 2B, and 2C illustrate an error correction circuit according to an embodiment of the present inventive concept.

FIG. 3 is a flowchart illustrating a method of operating a storage device according to an embodiment of the present inventive concept.

FIGS. 4A and 4B illustrate an effect of increasing reliability of a memory cell of a storage device according to an embodiment of the present inventive concept.

FIG. 5 is a view conceptually illustrating an error correction operation of a storage device according to an embodiment of the present inventive concept.

FIG. 6 is a flowchart illustrating a method of operating a storage device according to an embodiment of the present inventive concept.

FIG. 7 is a ladder diagram illustrating a read operation of a storage device according to an embodiment of the present inventive concept.

FIG. 8 is a view illustrating a storage device according to an embodiment of the present inventive concept.

FIG. 9 is a view illustrating a data center to which a memory device according to an embodiment of the present inventive concept is applied.

### DETAILED DESCRIPTION OF THE EMBODIMENTS

Hereinafter, embodiments of the present inventive concept will be described with reference to the accompanying drawings.

According to an embodiment of the present inventive concept, a storage device and operating method thereof may correct an additional symbol error by utilizing failure information related to a memory cell. For instance, the storage device and method of the present invention may set erasure using the failure information and perform ECC decoding using the set erasure. The failure information referred to above may include ECC history information. According to an embodiment of the present inventive concept, a storage device and operating method thereof may perform ECC decoding using error correction history information of memory cells, along with a result of inferring a defect based on the history information, to increase the reliability of the memory cells.

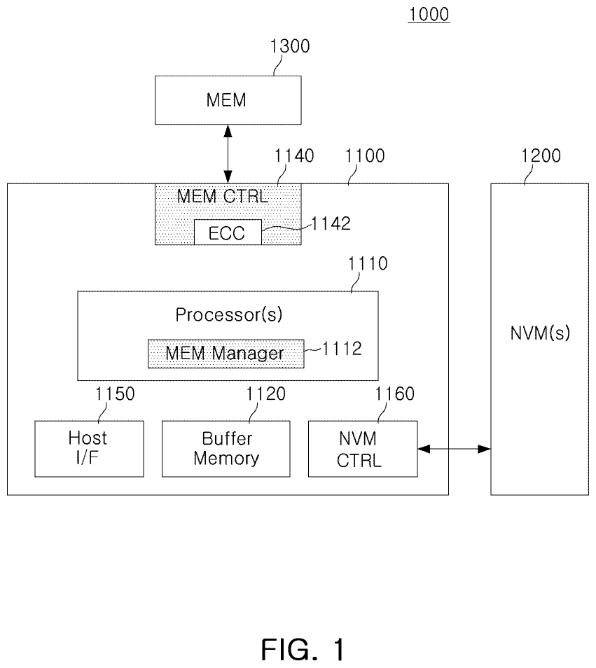

FIG. 1 is a view illustrating a storage device 1000 according to an embodiment of the present inventive concept. Referring to FIG. 1, a storage device 1000 may include a controller 1100, at least one non-volatile memory device 1200 (NVM(s)), and a memory device 1300 (DRAM).

The controller 1100 may be configured to control an overall operation of the storage device 1000. The controller 1100 may include at least one processor (e.g., a central processing unit (CPU)(s)) 1110, a buffer memory 1120, a memory controller 1140, a host interface circuit 1150, and a non-volatile memory controller 1160.

The at least one processor 1110 may be configured to control an overall operation of the controller 1100. The processor 1110 may be configured to drive a direct memory access (DMA) engine. In this case, the DMA engine may control a direct memory access (DMA) operation of the storage device 1000. The DMA engine may perform data transmission with a host device or an external device under the control of the processor 1110. For example, the DMA engine may transmit read data, which is loaded into the memory device 1300, as a stream to the host device in a DMA transmission mode. In addition, the DMA engine may store stream data provided from the host device in the memory device 1300 in the DMA transmission mode. In practice, the DMA engine may perform a DMA operation between the host device and the memory device 1300.

In addition, the processor 1110 may execute a volatile memory manager 1112 for managing reliability of the memory device 1300. The volatile memory manager 1112 may be configured to store and manage failure information of the memory device 1300. For example, the volatile memory manager 1112 may additionally correct a symbol error using a patrol read result of the memory device 1300 in the storage device 1000.

The buffer memory 1120 may be configured to temporarily store data necessary for an operation of the controller 1100. The buffer memory 1120 may be implemented as a volatile memory (e.g., a static random access memory (SRAM), a dynamic RAM (DRAM), a synchronous RAM (SDRAM), or the like) or a non-volatile memory (e.g., a flash memory, a phase-change RAM (PRAM), a magneto-resistive RAM (MRAM), a resistive RAM (ReRAM), a ferro-electric RAM (FRAM), or the like).

The memory controller 1140 may be configured to control the memory device 1300. The memory controller 1140 may write data to the memory device 1300 or read data that is stored in the memory device 1300 under the control of the processor 1110. In this case, the memory controller 1140 may include a buffer allocation unit for managing the memory device 1300 as a buffer. The buffer allocation unit may manage use and release of the memory device 1300.

In addition, the memory controller 1140 may be a volatile memory controller and may include an error correction circuit (ECC) 1142 for correcting an error in data of the memory device 1300.

The error correction circuit 1142 may be configured to detect and correct the error in data read from the memory device 1300 using an error correction code. In addition, when writing data to the memory device 1300 or reading data stored in the memory device 1300, the error correction circuit 1142 may encode or decode data through erasure coding. In this case, in the erasure coding, data may be encoded using an erasure code, and, when data is lost, original data may be restored through a decoding process. For example, the erasure code may include a Reed Solomon code, a Tahoe Least-Authority File System (Tahoe-LAFS), an EVENODD code, a Weaver code, an X-code, or the like.

The host interface circuit 1150 may be configured to communicate with the host device. The host interface circuit 1150 may be configured to transmit and receive a packet to and from the host device. The packet transmitted from the host device to the host interface circuit 1150 may include a command or data that is to be written to the non-volatile memory device 1200. The packet transmitted from the host interface circuit 1150 to the host device may include a response to a command or data that is to be read from the non-volatile memory device 1200.

In an embodiment of the present inventive concept, the host interface circuit 1150 may be interchangeable with at least one of a peripheral component interconnect express (PCIe) interface standard, a universal serial bus (USB) interface standard, a compact flash (CF) interface standard, a multi-media card (MMC) interface standard, an embedded MMC (eMMC) interface standard, a thunderbolt interface standard, a universal flash storage (UFS) interface standard, a secure digital (SD) interface standard, a memory stick interface standard, an extreme digital (xD)-picture card interface standard, an integrated drive electronics (IDE) interface standard, a serial advanced technology attachment (SATA) interface standard, a small computer system interface (SCSI) interface standard, a serial attached SCSI (SAS) interface standard, or an enhanced small disk interface (ESDI) interface standard.

The non-volatile memory controller 1160 may be configured to control the non-volatile memory device 1200. The non-volatile memory controller 1160 may perform various management operations such as cache/buffer management, firmware management, garbage collection management, wear leveling management, data deduplication management, read refresh/reclaim management, bad block management, multi-stream management, mapping management of host data and a non-volatile memory, quality of service (QoS) management, system resource allocation management, non-volatile memory queue management, read level management, erase/program management, hot/cold data management, power loss protection management, dynamic thermal management, initialization management, a redundant array of inexpensive disk (RAID) management, and/or the like.

The non-volatile memory controller 1160 may transmit a command and an address to a NAND flash memory device of the non-volatile memory device 1200, to perform a program operation, a read operation, an erase operation, or the like. The non-volatile memory controller 1160 may be connected to the non-volatile memory device 1200 through a plurality of control pins transmitting control signals (e.g., CLE, ALE, CE(s), WE, RE, or the like). In addition, the non-volatile memory controller 1160 may be configured to control the non-volatile memory device 1200 using the control signals (CLE, ALE, CE(s), WE, RE, or the like). For example, the NAND flash memory device may latch a command or an address at an edge of a write enable (WE)/read enable (RE) signal according to a command latch enable (CLE) signal and an address latch enable (ALE) signal, to perform a program operation/a read operation/an erase operation. For example, in a read operation, a chip enable signal CE may be activated, and CLE may be activated during a command transmission period. In addition, ALE may be activated during an address transmission period, and RE may be toggled through a data signal line DQ during a period transmitting data. A data strobe signal DQS may be toggled at a frequency corresponding to a data input/output speed. Read data may be sequentially transmitted in synchronization with the data strobe signal DQS.

In an embodiment of the present inventive concept, the non-volatile memory controller 1160 may be configured to comply with a standard protocol such as a joint electron device engineering council (JEDEC) toggle or an open NAND flash interface (ONFI).

In addition, the non-volatile memory controller 1160 may include a flash translation layer manager. The flash translation layer manager may perform several functions such as address mapping, wear-leveling, or garbage collection.

In addition, the non-volatile memory controller 1160 may include a security module. The security module may perform at least one of an encryption operation or a decryption operation on data input to the processor 1110 by using a symmetric-key algorithm. The security module may include an encryption module and a decryption module. In an embodiment of the present inventive concept, the security module may be implemented in terms of hardware/software/firmware. The security module may be configured to perform security functions of the storage device 1000. For example, the security module may perform a self encryption disk (SED) function or a trusted computing group (TCG) security function.

The SED function may store encrypted data in the non-volatile memory device 1200 using an encryption algorithm, or may decrypt the encrypted data from the non-volatile memory device 1200. Such encryption/decryption operations may be performed using an encryption key, internally generated. In an embodiment of the present inventive concept, the encryption algorithm may be an advanced encryption standard (AES) encryption algorithm. It should be understood that the encryption algorithm might not necessarily be limited thereto. The TCG security function may provide a mechanism enabling access control to user data in the storage device 1000. For example, the TCG security function may perform an authentication procedure between the external device and the storage device 1000. In an embodiment of the present inventive concept, the SED function or the TCG security function may be optionally selected. In addition, the security module may be configured to perform an authentication operation with the external device or a fully homomorphic encryption function.

The non-volatile memory device 1200 may include at least one NAND flash memory device. For example, the NAND flash memory device may be implemented as a three-dimensional array structure. For example, the NAND flash memory device may be implemented as a vertical NAND flash memory device. The non-volatile memory device 1200 may be connected to the non-volatile memory controller 1160 through at least one channel. A plurality of NAND flash memory devices may be connected to the at least one channel. Each of the NAND flash memory devices may include a plurality of memory cells connected to wordlines and bitlines. In this case, each of the plurality of memory cells may be configured to store at least one bit.

The memory device 1300 may be used as a data buffer for exchanging data between the storage device 1000 and the host device. In addition, the memory device 1300 may store a mapping table for mapping a logical address provided to the storage device 1000 and an address of the non-volatile memory device 1200. The mapping table may be loaded from the non-volatile memory device 1200 to the memory device 1300 during an initialization operation of the storage device 1000. The memory device 1300 may temporarily store write data that is provided from the host device or data that is read from the non-volatile memory device 1200. When data existing in the non-volatile memory device 1200 is cached upon a read request from the host device, the memory device 1300 may support a cache function providing the cached data to the host device. In an embodiment of the present inventive concept, the memory device 1300 may be implemented as a dynamic random access memory (DRAM) to provide sufficient buffering in the storage device 1000.

In addition, the memory device 1300 may be configured to read data from a memory cell array and perform on-die error correction for correcting an error in the read data. The memory device 1300 may support an error check and scrub (ECS) mode. In the ECS mode, the memory device 1300 may internally correct an error bit of the memory cell array, may store failure information (e.g., an error address), and may report the failure information to an external controller.

A storage device 1000 according to an embodiment of the present inventive concept may perform an error correction code (ECC) that decodes using error correction history information of memory cells of the memory device 1300 and a result of inferred from the history information to detect failures. Thus, the storage device 1000 may increase reliability of the memory cells of the memory device 1300 and thereby expect to increase system performance.

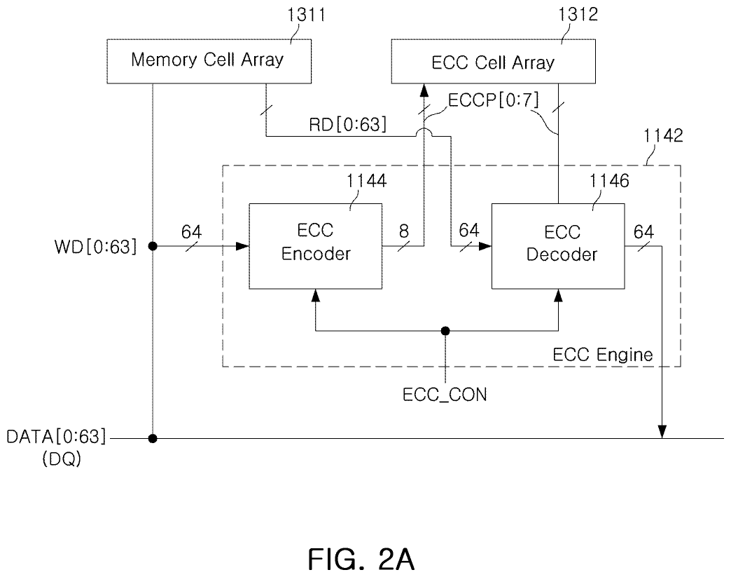

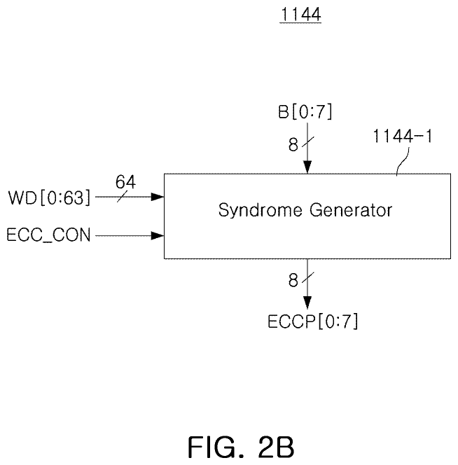

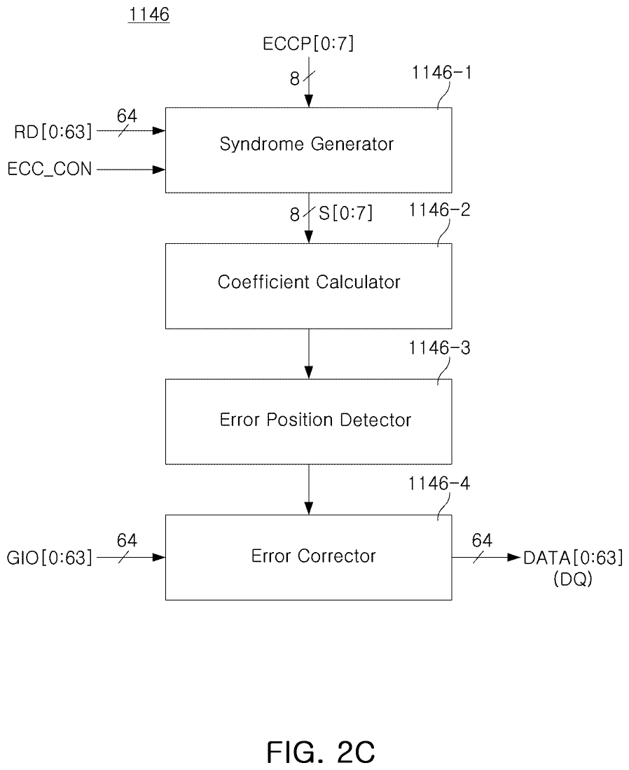

FIGS. 2A, 2B, and 2C illustrate an error correction circuit 1142 according to an embodiment of the present inventive concept.

Referring to FIG. 2A, an error correction circuit 1142 may include an ECC encoding circuit 1144 and an ECC decoding circuit 1146. The ECC encoding circuit 1144 may generate parity bits ECCP[0:7] for data WD[0:63], which is to be written to memory cells of a memory cell array 1311, in response to an ECC control signal ECC_CON. The parity bits ECCP[0:7] may be stored in an ECC cell array 1312. In an embodiment of the present inventive concept, the ECC encoding circuit 1144 may generate parity bits ECCP[0:7] for data WD[0:63], which is to be written to memory cells including defective cells, in response to the ECC control signal ECC_CON.

In response to the ECC control signal ECC_CON, the ECC decoding circuit 1146 may correct error bit data by using the data RD[0:63], which is read from the memory cells of the memory cell array 1311, and the parity bits ECCP[0:7], which are read from the ECC cell array 1312. The ECC decoding circuit 1146 may output error-corrected data Data[0:63]. In an embodiment of the present inventive concept, in response to the ECC control signal ECC_CON, the ECC decoding circuit 1146 may correct error bit data using the data RD[0:63], which is read from the memory cells including the defective cells, and the parity bits ECCP[0:7], which are read from the ECC cell array 1312, and the ECC decoding circuit 1146 may output error-corrected data Data[0:63].

Referring to FIG. 2B, an ECC encoding circuit 1144 may include a syndrome generator 1144-1 that is receiving 64-bit write data WD[0:63] and basis bits B[0:7] in response to an ECC control signal ECC_CON. The syndrome generator 1144-1 may generate parity bits ECCP[0:7], e.g., a syndrome, using an XOR array operation. The basis bits B[0:7] may be bits generating the parity bits ECCP[0:7] for the 64-bit write data WD[0:63], and may include, for example, b′00000000 bits. For example, the basis bits B[0:7] may use other specific bits, instead of the b′00000000 bits.

Referring to FIG. 2C, an ECC decoding circuit 1146 may include a syndrome generator 1146-1, a coefficient calculator 1146-2, a 1-bit error position detector 1146-3, and an error corrector 1146-4. The syndrome generator 1146-1 may receive 64-bit read data RD[0:63] and 8-bit parity bits ECCP[0:7] in response to an ECC control signal ECC_CON, and may generate syndrome data S[0:7] by using an XOR array operation. The coefficient calculator 1146-2 may calculate coefficients of an error position equation by using the syndrome data S[0:7]. In this case, the error position equation may be an equation of which root is a reciprocal of an error bit. The 1-bit error location detector 1146-3 may calculate a location of a 1-bit error by using the calculated error location equation. The error corrector 1146-4 may determine a location of the 1-bit error based on a detection result of the 1-bit error location detector 1146-3. The error corrector 1146-4 may correct the error by inverting a logic value of a bit in which an error is generated, among 64-bit read data RD[0:63], according to determined information of the location of the 1-bit error, and the error corrector 1146-4 may output error-corrected 64-bit data DATA[0:63].

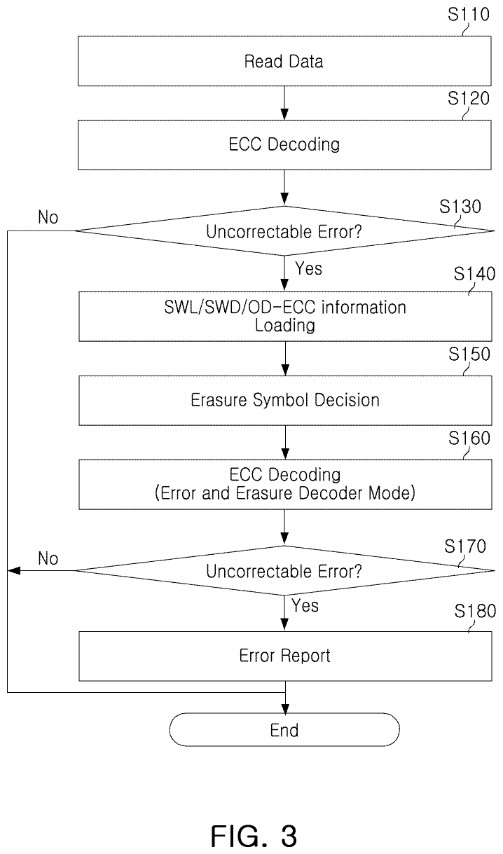

FIG. 3 is a flowchart illustrating a method of operating a storage device 1000 according to an embodiment of the present inventive concept. Referring to FIGS. 1 to 3, a storage device 1000 may perform error correction as follows.

The memory controller 1140 may read data from the memory device 1300 (S110). The memory controller 1140 may perform an ECC decoding operation on read data (S120). As a result of the ECC decoding operation, the memory controller 1140 may determine whether the read data is an error that is uncorrectable (S130). When error correction of the read data is impossible, the error is corrected and the read operation may be terminated. When the read data is an error that is uncorrectable, the memory controller 1140 may load failure information related to sub wordline (SWL)/sub wordline drive (SWD)/on-die error correction code (OD-ECC), stored in advance (S140). The memory controller 1140 may determine an erasure symbol based on the failure information (S150). The memory controller 1140 may perform ECC decoding on read data by using the determined erasure symbol (S160). Thereafter, the memory controller 1140 may determine again whether the read data is an error that is uncorrectable (S170). When error correction of the read data is impossible, the error is corrected and the read operation may be terminated. When the read data is an error that is uncorrectable, the memory controller 1140 may output an error report on the read operation to the processor 1110 (see FIG. 1) (S180). Then, the read operation may be completed.

A method of operating a storage device 1000 according to an embodiment of the present inventive concept may perform ECC decoding, and when an UE (Uncorrectable Error) occurs, the method may store failure information such as SWL failure information, SWD failure information, on-die ECC history information, or the like, which are stored for management of the memory device 1300, may determine an erasure symbol based on the failure information, and may additionally perform ECC decoding on the read data in an error and erasure decoder mode. In an embodiment of the present inventive concept, the error and erasure decoder mode may optionally be performed. The error and erasure decoder mode may be set periodically/aperiodically according to an internal policy or an external request.

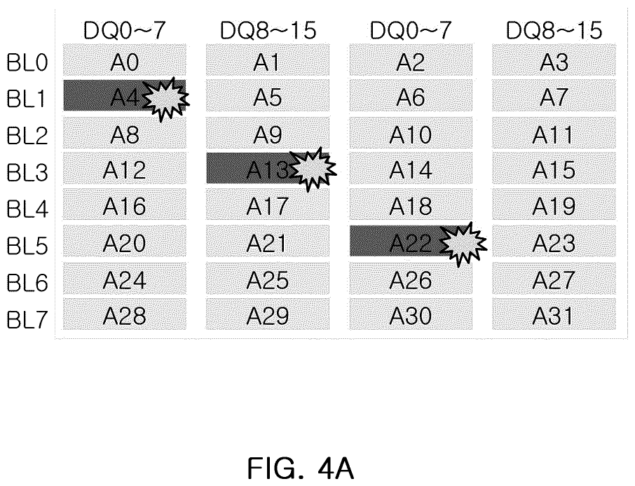

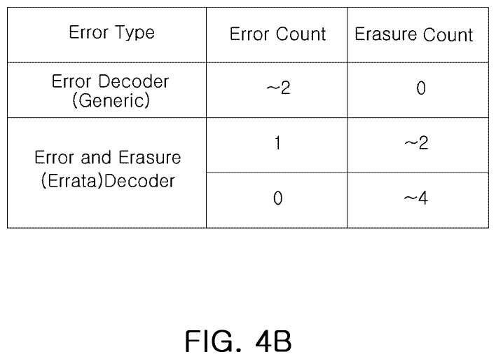

FIGS. 4A and 4B illustrate an effect of increasing reliability of a memory cell of a storage device 1000 according to an embodiment of the present inventive concept.

A storage device 1000 according to an embodiment of the present inventive concept may correct an additional symbol error, without additional overhead, based on failure information of a memory device 1300 (e.g., DRAM).

As illustrated in FIG. 4A, failure information due to an SWL defect may be predicted by monitoring. Based on the failure information, erasure symbol processing may be possible. An erasure symbol may be a location of a symbol on which an error occurred.

Assuming that an error correction circuit has a 2-RC code error correction capability, a general storage device might not correct errors generated in A4, A13, and A22, as illustrated in FIG. 4A. However, as depicted in FIG. 4B, a storage device 1000 according to an embodiment of the present inventive concept may process erasure symbols in A3, A13, and A22, even when a 2-RC code is used, to correct three errors in total. In an embodiment of the present inventive concept, a first error correction operation (e.g., hard decision decoding) using an error decoder may perform an error correction operation based on an error count. Additionally, a second error correction operation (e.g., soft decision decoding) using an error and erasure decoder may perform an error correction operation based on an error count and an erasure count. The first error correction operation and the second error correction operation may have different correction capabilities from each other.

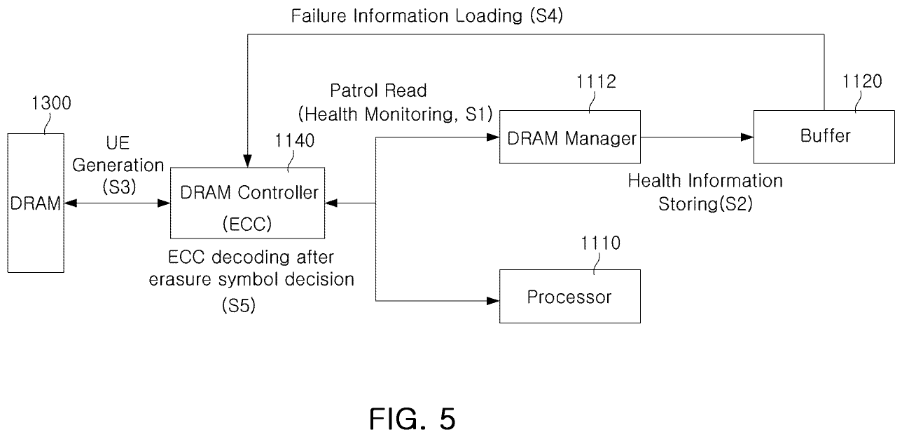

FIG. 5 is a view conceptually illustrating an error correction operation of a storage device 1000 according to an embodiment of the present inventive concept. Referring to FIG. 5, an error correction operation of a storage device 1000 may proceed as follows.

A memory manager 1112 of the storage device 1000 may monitor health information, such as ECC decoding information or the like, of a memory device 1300 (DRAM) by a patrol read at regular intervals (S1). The storage device 1000 may store the monitored health information in a buffer memory 1120 when CE and issues occur (S2). In this case, the buffer memory 1120 to be stored may be a static random access memory (SRAM)/a dynamic RAM (DRAM)/a NAND flash memory/a serial NOR flash memory (SNOR) or the like. The health information may include location information (failure information) in which a defect occurs. This operation may be equally applied, even in reading by a host. Thereafter, in processing a read request for the memory device 1300, an UE (Uncorrectable Error) may occur (S3). When the UE occurs, the volatile memory controller 1140 may load the health information described above (S4). In addition, the volatile memory controller 1140 may determine an erasure symbol based on the health information and may perform ECC decoding to correct the error (S5).

In an embodiment of the present inventive concept, the failure information may include sub wordline failure information, sub wordline driver failure information, or on-die error correction code (OD-ECC) operation information. The error correction operation may include a first error correction operation that operates based on an error count and a second error correction operation that operates based on an error count and an erasure count. The first error correction operation and the second error correction operation may have different correction capabilities from each other. In an embodiment of the present inventive concept, the erasure may be determined based on the failure information. In an embodiment of the present inventive concept, if error correction is not possible as a result of the second error correction operation, an error report may be generated. In an embodiment of the present inventive concept, an error and erasure decoder mode may be set to perform the second error correction operation. In an embodiment of the present inventive concept, both the first error correction operation and the second error correction operation may perform error correction using Reed Solomon codes.

In an embodiment of the present inventive concept, the storage device 1000 may include at least one non-volatile memory device 1200 and a controller 1100 that controls at least one volatile memory device, and the controller 1100 can control the memory device 1300 by the memory manager 1112. When a UE occurs in the memory device 1300, a storage device 1000 according to an embodiment of the present inventive concept uses the health information stored in the buffer memory 1120 to perform a defense code for correcting a data error, as described above.

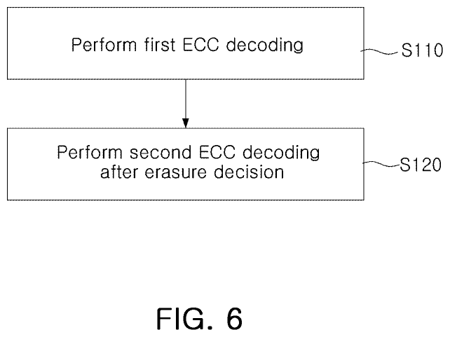

FIG. 6 is a flowchart illustrating a method of operating a storage device 1000 according to an embodiment of the present inventive concept. Referring to FIGS. 1 to 6, a storage device 1000 may perform a read operation as follows.

The storage device 1000 may perform first ECC decoding on data read from a memory device 1300 (S110). When error correction is impossible in the first ECC decoding, after determining an erasure by using failure information, which is previously stored and related to the memory device 1300, the storage device 1000 may perform second ECC decoding (S120).

In an embodiment of the present inventive concept, the first ECC decoding may include performing an error correction operation based on an error count. In an embodiment of the present inventive concept, the second ECC decoding may include performing an error correction operation based on an error count and an erasure count. In an embodiment of the present inventive concept, the second ECC decoding may further include setting an erasure using failure information. In an embodiment of the present inventive concept, failure information on the memory device 1300 may be periodically/non-periodically collected according to an internal policy or an external request.

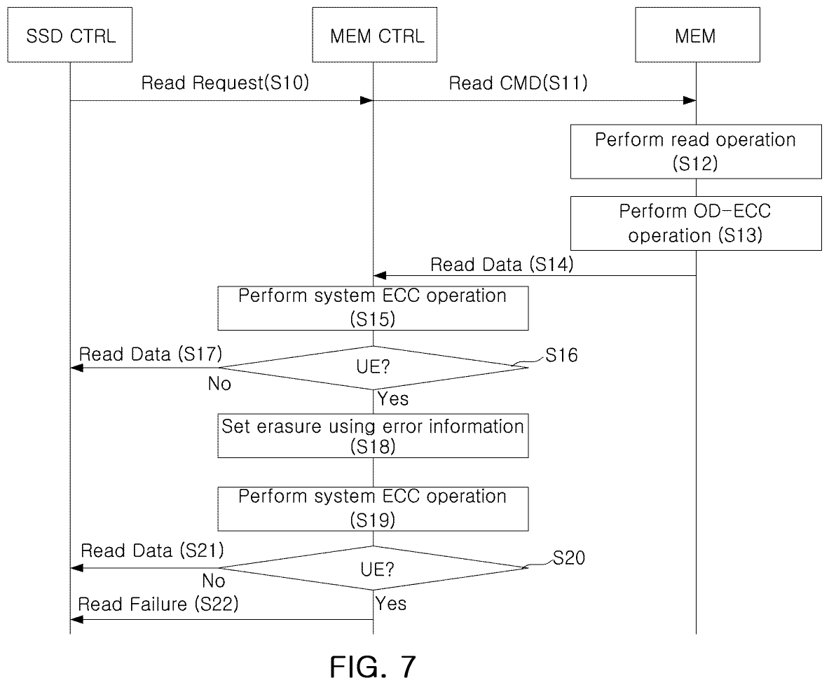

FIG. 7 is a ladder diagram illustrating a read operation of a storage device according to an embodiment of the present inventive concept. Referring to FIG. 7, a read operation of a storage device (SSD) may operate as follows.

A storage device controller SSD CTRL may output a read request to a memory controller MEM CTRL (S10). The memory controller MEM CTRL may transmit a read command according to the received read request to a memory device MEM (S11). The memory device MEM may perform a read operation in response to a read command (S12). The memory device MEM may perform an on-die error correction operation on read data (S13). The memory device MEM may transmit error-corrected data to the memory controller MEM CTRL (S14). The memory controller MEM CTRL may perform a system error correction operation on the transmitted data (S15). The memory controller MEM CTRL may determine whether an uncorrectable error (UE) has occurred as determined by the system error correction operation (S16). When data is not error uncorrectable, the error-corrected data may be output to the storage device controller SSD CTRL (S17). When data is not error uncorrectable, the memory controller MEM CTRL may set an erasure using failure information (S18). In this case, the failure information may include failure information of the memory device MEM.

Thereafter, the memory controller MEM CTRL may perform a system error correction operation on the transmitted data (S19). The memory controller MEM CTRL may determine whether an uncorrectable error (UE) has occurred as a result of the system error correction operation (S20). When data is not error uncorrectable, the error-corrected data may be output to the storage device controller SSD CTRL (S21). When data is not error uncorrectable, the memory controller MEM CTRL may output read failure information to the storage device controller SSD CTRL (S22).

In FIG. 1, an error correction circuit is illustrated as an internal configuration of the memory controller, according to an embodiment of the present inventive concept. It should be understood that the present inventive concept is not necessarily limited thereto. The error correction circuit may be separately disposed outside the memory controller, and may perform an error correction operation on data of a non-volatile memory device as well as data of a volatile memory device.

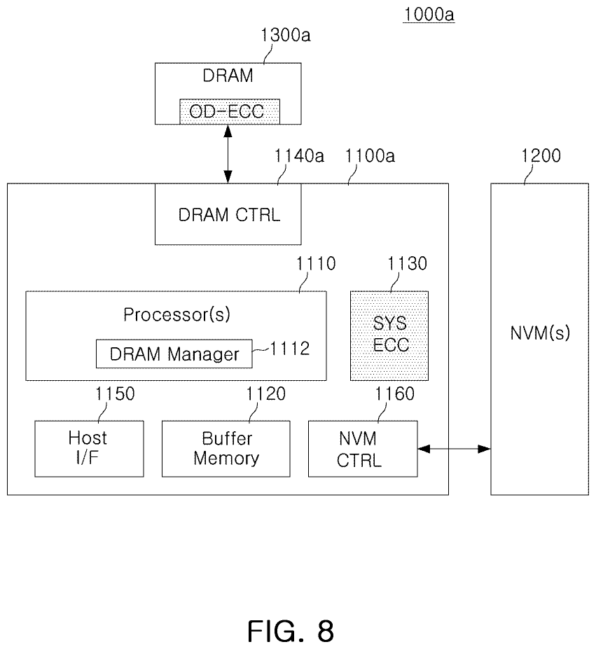

FIG. 8 is a view illustrating a storage device 1000a according to an embodiment of the present inventive concept. Referring to FIG. 8, a storage device 1000a may include a controller 1100a having a system error correction circuit 1130, compared to that illustrated in FIG. 1. In this case, the system error correction circuit 1130 may perform an error correction operation on data of a memory device 1300a, or may perform an error correction operation on data of a non-volatile memory device 1200, as described in FIGS. 1 to 7.

The system error correction circuit 1130 may generate an error correction code for correcting a failure bit or an error bit of data received from the non-volatile memory device 1200. The system error correction circuit 1130 may perform error correction encoding on data that is provided to the non-volatile memory device 1200, to form data to which parity bits are added. The parity bits may be stored in the non-volatile memory device 1200. In addition, the system error correction circuit 1130 may perform error correction decoding on data that is output from the non-volatile memory device 1200. The system error correction circuit 1130 may correct errors using parity bits. The system error correction circuit 1130 may use coded modulation such as a low density parity check (LDPC) code, a BCH code, a Turbo code, a Reed Solomon code, a convolution code, a recursive systematic code (RSC), a Trellis-Coded Modulation (TCM), block coded modulation (BCM), or the like, to correct an error. When error correction is impossible in the system error correction circuit 1130, a read retry operation may be performed.

A storage device according to an embodiment of the present inventive concept may be applicable to a data server system.

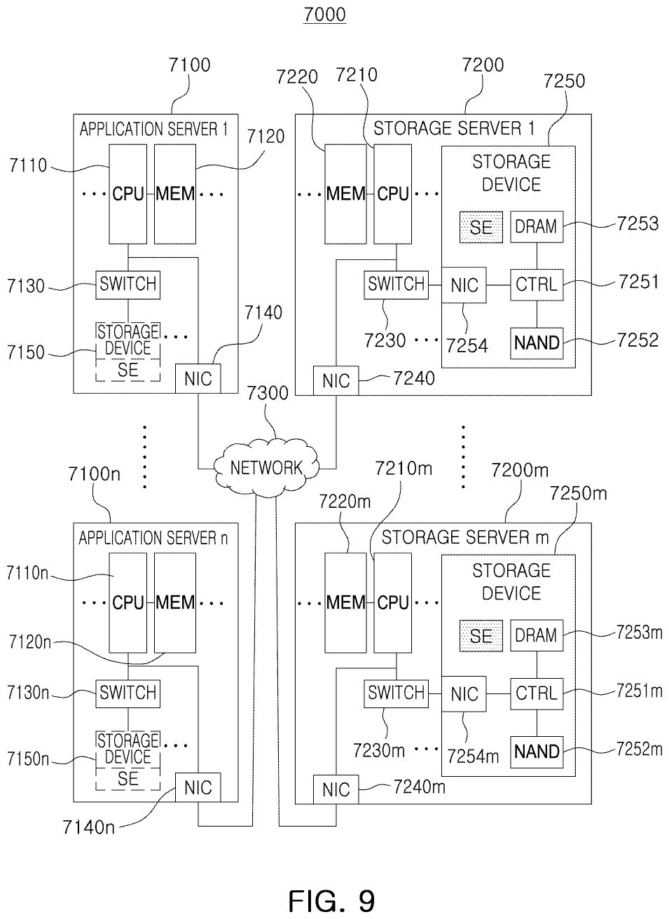

FIG. 9 is a view illustrating a data center to which a memory device according to an embodiment of the present inventive concept is applied. Referring to FIG. 9, a data center 7000 may be a facility that stores various types of data and provides services, and may also be referred to as a data storage center. The data center 7000 may be a system for operating a search engine and database, and may be a computing system used by companies such as banks or the like, or government agencies. The data center 7000 may include application servers 7100 to 7100n and storage servers 7200 to 7200m. The number of application servers 7100 to 7100n and the number of storage servers 7200 to 7200m may be variously selected according to embodiments of the present inventive concept, and the number of application servers 7100 to 7100n may be different from the number of storage servers 7200 to 7200m.

The application server 7100 or the storage server 7200 may include at least one of processors 7110 and 7210 and at least one of memories 7120 and 7220. Referring to the storage server 7200 as an example, the processor 7210 may control an overall operation of the storage server 7200, may access the memory 7220, and may execute instructions and/or data loaded into the memory 7220. The memory 7220 may be, for example, a double data rate synchronous DRAM (DDR SDRAM), a high bandwidth memory (HBM), a hybrid memory cube (HMC), a dual in-line memory module (DIMM), an optane DIMM, or a non-volatile DIMM (NVMDIMM). According to embodiments of the present inventive concept, the number of processors 7210 and the number of memories 7220 included in the storage server 7200 may be variously selected. In an embodiment of the present inventive concept, the processor 7210 and the memory 7220 may provide a processor-memory pair. In an embodiment of the present inventive concept, the number of processors 7210 may be different from the number of memories 7220. The processor 7210 may include a single core processor or a multi-core processor. The above description of the storage server 7200 may be similarly applied to the application server 7100. According to embodiments of the present inventive concept, the application server 7100 might not include a storage device 7150. The storage server 7200 may include at least one storage device 7250. The number of storage devices 7250 included in the storage server 7200 may be variously selected according to embodiments of the present inventive concept.

The application servers 7100 to 7100n and the storage servers 7200 to 7200m may communicate with each other through a network 7300. The network 7300 may be implemented by using a fiber channel (FC) or an ethernet. In this case, FC may be a medium used for relatively high-speed data transmission, and may use an optical switch that provides high performance/high availability. Depending on an access method of the network 7300, the storage servers 7200 to 7200m may be provided as, for example, file storage, block storage, or object storage.

In an embodiment of the present inventive concept, the network 7300 may be a storage network such as a storage area network (SAN). For example, the SAN may be an FC-SAN that uses an FC network, and may be implemented according to an FC protocol (FCP). As another example, the SAN may be an IP-SAN using a TCP/IP network, and may be implemented according to an iSCSI (SCSI over TCP/IP or Internet SCSI) protocol. In an embodiment of the present inventive concept, the network 7300 may be a general network such as a TCP/IP network. For example, the network 7300 may be implemented according to protocols such as an FC over ethernet (FCoE), a network attached storage (NAS), an NVMe over Fabrics (NVMe-oF), or the like.

Hereinafter, the application server 7100 and the storage server 7200 will be mainly described. The description of the application server 7100 may also be applied to other application servers 7100n, and the description of the storage server 7200 may also be applied to other storage servers 7200m.

The application server 7100 may store data that is requested by a user or a client to be stored in one of the storage servers 7200 to 7200m through the network 7300. In addition, the application server 7100 may acquire data requested by a user or a client to be read from one of the storage servers 7200 to 7200m through the network 7300. For example, the application server 7100 may be implemented as a web server or a database management system (DBMS).

The application server 7100 may access a memory 7120n and/or a storage device 7150n, which are included in the application server 7100n, through the network 7300, or may access the memories 7220 to 7220m and/or the storage devices 7250 to 7250m, which are included in the storage servers 7200 to 7200m, through the network 7300. Therefore, the application server 7100 may perform various operations on data that is stored in the application servers 7100 to 7100n and/or the storage servers 7200 to 7200m. For example, the application server 7100 may execute a command for moving or copying data between the application servers 7100 to 7100n and/or the storage servers 7200 to 7200m. In this case, the data may be moved from the storage devices 7250 to 7250m of the storage servers 7200 to 7200m to the memories 7120 to 7120n of the application servers 7100 to 7100n through the memories 7220 to 7220m of the storage servers 7200 to 7200m, or may be moved directly to the memories 7120 to 7120n of the application servers 7100 to 7100n. For example, data moving through the network 7300 may be encrypted data for security or privacy.

Referring to the storage server 7200 as an example, an interface 7254 may provide a physical connection between a processor 7210 and a controller 7251 and between an NIC 7240 and the controller 7251. For example, the interface 7254 may be implemented in a direct attached storage (DAS) method that directly connects the storage device 7250 with a dedicated cable. In addition, for example, the interface 1254 may be implemented in various interface methods such as an advanced technology attachment (ATA), a serial ATA (SATA), an external SATA (e-SATA), a small computer small interface (SCSI), a serial attached SCSI (SAS), a peripheral component interconnection (PCI), a PCI express (PCIe), an NVM express (NVMe), IEEE 1394, a universal serial bus (USB), a secure digital (SD) card, a multi-media card (MMC), an embedded multi-media card (eMMC), an universal flash storage (UFS), an embedded universal flash storage (eUFS), a compact flash (CF) card interface, or the like.

The storage server 7200 may further include a switch 7230 and a NIC 7240. The switch 7230 may selectively connect the processor 7210 and the storage device 7250 to each other, or may selectively connect the NIC 7240 and the storage device 7250 to each other under control of the processor 7210.

In an embodiment of the present inventive concept, the NIC 7240 may include a network interface card, a network adapter, or the like. The NIC 7240 may be connected to the network 7300 through a wired interface, a wireless interface, a Bluetooth interface, an optical interface, or the like. The NIC 7240 may include, for example, an internal memory, a DSP, a host bus interface, or the like, and may be connected to the processor 7210 and/or the switch 7230, or the like, through the host bus interface. The host bus interface may be implemented as one of the examples of interface 7254 described above. In an embodiment of the present inventive concept, the NIC 7240 may be integrated with at least one of the processor 7210, the switch 7230, and/or the storage device 7250.

In the storage servers 7200 to 7200m or the application servers 7100 to 7100n, the processor may transmit a command to the storage devices 7150 to 7150n and 7250 to 7250m or the memories 7120 to 7120n and 7220 to 7220m, to program or read data. In this case, the data may be error-corrected data through an error correction code (ECC) engine. The data may be data bus inversion (DBI) or data masking (DM) processed data, and may include cyclic redundancy code (CRC) information. For example, the data may be encrypted data for security or privacy.

The storage devices 7150 to 7150m and 7250 to 7250m may transmit a control signal and command/address signals to the NAND flash memory devices 7252 to 7252m in response to a read command received from the processor. Therefore, when data is read from the NAND flash memory devices 7252 to 7252m, a read enable (RE) signal may be input as a data output control signal, and may serve as outputting data to a DQ bus. A data strobe (DQS) may be generated by using the RE signal. Command and address signals may be latched in a page buffer according to a rising edge or a falling edge of a write enable (WE) signal.

In an embodiment of the present inventive concept, the storage devices 7150 to 7150m and 7250 to 7250m may perform a read operation according to the storage devices and the methods, described in FIGS. 1 to 8.

The controller 7251 may control an overall operation of the storage device 7250. In an embodiment of the present inventive concept, the controller 7251 may include a static random access memory (SRAM). The controller 7251 may write data to the NAND flash memory 7252 in response to a write command, or may read data from the NAND flash memory 7252 in response to a read command. For example, the write command and/or the read command may be provided from the processor 7210 in the storage server 7200, the processor 7210m in the storage server 7200m, or the processor 7110 or 7110n in the application server 7100 or 7100n. The DRAM 7253 may temporarily store (e.g., buffer) data to be written to the NAND flash memory 7252 or data read from the NAND flash memory 7252. In addition, the DRAM 7253 may store meta data. In this case, the meta data may be user data or data generated by the controller 7251 to manage the NAND flash memory 7252.

The present inventive concept can increase ECC correction capability of a storage device (SSD) without increasing cell overhead, by utilizing failure information of a DRAM stored in the SSD. In an embodiment of the present inventive concept, the SSD may collect failure information of the DRAM at predetermined intervals, including SWD failure information, SWL failure information, On Die ECC history information, or other relevant information. The failure information can be stored in DRAM/SRAM/NAND/SNOR. In case of an uncorrectable error (UE) in the DRAM, an erasure symbol (e.g., a location where the error occurred) can be selected based on the corresponding failure information, and erasure decoding can be performed on the changed erasure symbol to correct the error.

According to an embodiment of the present inventive concept, after a write operation, a corresponding page may be read regardless of the host's read request. During a recovery operation after an ECC decoding failure, data in a specific page can be read. This approach efficiently utilizes cell overhead, compared to increasing ECC parity, to overcome wordline and page variation within a block.

In an embodiment of the present inventive concept, a storage device and a method of operating the same can perform ECC decoding using an error correction history of a cell and inferring defects based on this history to increase the reliability of a DRAM cell.

While the present inventive concept has been described with reference to embodiments thereof, it will be understood by those of ordinary skill in the art that various changes in form and details may be made thereto without departing from the spirit and scope of the present inventive concept.

1. A method of operating a storage device, comprising:
periodically performing a patrol read operation on a memory device;
storing failure information according to the patrol read operation in a buffer memory;
generating an uncorrectable error as a result of a first error correction operation performed on read data of the memory device;
loading the failure information from the buffer memory; and
performing a second error correction operation on the read data by using the failure information.

2. The method of claim 1, wherein the failure information comprises sub wordline failure information, sub wordline driver failure information, or on-die error correction history information.

3. The method of claim 1, wherein the buffer memory comprises at least one of a dynamic random access memory (DRAM), a static random access memory (SRAM), a NAND flash memory, or a serial NOR (SNOR) flash memory.

4. The method of claim 1, wherein the first error correction operation and the second error correction operation have different correction capabilities from each other.

5. The method of claim 1, wherein the performing the second error correction operation comprises determining an erasure by using the failure information.

6. The method of claim 1, further comprising setting an error and erasure decoder mode to perform the second error correction operation.

7. The method of claim 1, further comprising reporting error information when an uncorrectable error has occurred as a result of the second error correction operation.

8. The method of claim 1, wherein each of the first error correction operation and the second error correction operation performs error correction using a Reed Solomon code.

9. The method of claim 1, wherein the first error correction operation determines a correction capability according to an error count, and
the second error correction operation determines a correction capability according to the error count and an erasure count.

10. The method of claim 1, wherein the storage device comprises a controller configured to control at least one non-volatile memory device and at least one volatile memory device,
wherein the controller controls the memory device by using a memory manager.

11. A storage device, comprising:
at least one non-volatile memory device;
a memory device; and
a controller configured to control the at least one non-volatile memory device,
wherein the controller periodically collects failure information of the memory device through a patrol read operation, and determines an erasure using the failure information, wherein the controller performs an error correction operation on read data by using the determined erasure.

12. The storage device of claim 11, wherein the controller comprises a non-volatile memory controller and a memory controller, wherein the non-volatile memory controller controls the at least one non-volatile memory device, and the memory controller controls the memory device,
wherein the memory controller performs the error correction operation on the read data.

13. The storage device of claim 11, wherein the controller further comprises a buffer memory configured to store the failure information.

14. The storage device of claim 11, wherein the controller further comprises a processor configured to drive a memory manager that controls the patrol read operation.

15. The storage device of claim 11, wherein the wherein the controller sets an error and erasure decoder mode to perform the error correction operation according to an internal policy or an external request.

16. A method of operating a storage device, comprising:
performing a first error correction operation on read data of a memory device; and
performing a second error correction operation by using failure information of the memory device when an error of the read data is uncorrectable as determined by the first error correction operation.

17. The method of claim 16, wherein the performing the first error correction operation comprises performing an error correction operation based on an error count.

18. The method of claim 16, wherein the performing the second error correction operation comprises performing an error correction operation based on an error count and an erasure count.

19. The method of claim 18, wherein the performing the second error correction operation further comprises setting an erasure by using the failure information.

20. The method of claim 16, further comprising collecting the failure information for the memory device.

21-25. (canceled)
